(19) United States
(12) Patent Application Publication
(10) Pub. No.: US 2016/0060761 A1
(43) Pub. Date: Mar. 3, 2016

(54) METHOD FOR MANUFACTURING A CARBON-CONTAINING PROTECTIVE FILM

(71) Applicant: FUJI ELECTRIC (MALAYSIA) SDN, BHD., Kulim (MY)

(72) Inventor: Naruhisa NAGATA, Matsumoto-city (JP)

(73) Assignee: FUJI ELECTRIC (MALAYSIA) SDN, BHD., Kulim (MY)

(21) Appl. No.: 14/937,848

(22) Filed: Nov. 10, 2015

Related U.S. Application Data
(63) Continuation of application No. PCT/MY2013/000193, filed on Nov. 14, 2013.

(51) Int. Cl. C23C 16/50; G11B 5/84

(52) U.S. Cl. CPC C23C 16/50; G11B 5/8408

(57) ABSTRACT

A method for manufacturing a protective film having a smaller thickness that none-the-less suppresses degradation of the protective film and maintains corrosion resistance is achieved. The method for manufacturing a carbon-containing protective film includes: (a) forming a carbon material film on a substrate by a plasma CVD method using a starting material gas containing a hydrocarbon gas; and (b) nitriding the carbon material film by using plasma generated from a nitrogen-containing starting material gas in a plasma CVD device having an anode and a cathode, to form the carbon-containing protective film. During nitriding, an anode potential may be equal to or greater than 20 V, an ion acceleration potential difference may be within a range of 20 V to 120 V, and a substrate current density may be within a range of 4×10⁻⁶ A/mm² to 8×10⁻⁶ A/mm².

### CROSS-REFERENCE TO RELATED APPLICATION(S)

This non-provisional Application for a U.S. Patent is a Continuation of International Application PCT/MY2013/000193 filed Nov. 14, 2013, the entire contents of which is hereby incorporated by reference.

### BACKGROUND OF THE INVENTION

1. Field of the Invention

The present invention relates to a method for manufacturing a carbon-containing protective film for covering and protecting a substance. More specifically, the present invention relates to a method for manufacturing a carbon-containing protective film suitable for use in a magnetic recording medium.

2. Background of the Related Art

Protective films constituted by carbon-containing materials have been recently used for covering and protecting substances. In particular, because of excellent performance thereof, such as hardness and durability, protective films constituted by carbon-containing materials formed using a plasma CVD method have been used for a variety of applications.

For example, such protective films are also often used in the field of magnetic recording media. In order to increase the recording density of hard disk drives (HDD), it is necessary to improve a magnetic recording layer and, at the same time, reduce as much as possible the distance (magnetic spacing) between a magnetic head that reads and writes information and the magnetic recording layer. The measures, such as thickness reduction of the protective film formed on the magnetic recording layer, thickness reduction of the lubricating film formed on the protective film, and decrease in flying height of the magnetic head, have been used for this purpose. In addition, a flying-on-demand (FOD) technique of reducing the effective flying height by causing the element section of the magnetic head to protrude has been also used.

Diamond-like carbon (DLC) films have been used as protective films having good durability in magnetic recording media. The object of the protective film in a magnetic recording medium is to protect the magnetic recording layer from damage caused by contact or sliding of the magnetic head and also from corrosion. Japanese Patent Application Publication No. 2010-55680 suggests the technique for enhancing the coupling between the protective film and the lubricating film and inhibiting the adsorption of contamination gas by nitriding the protective film surface.

However, the aforementioned nitridation treatment may degrade the protective film and reduce corrosion resistance of the protective film. Such decrease in corrosion resistance of the protective film results in the decreased reliability of the protective film. The decrease in corrosion resistance of the protective film is especially significant when the protective film thickness is small, in particular when the protective film thickness is equal to or less than 2.5 nm. Where the protective film thickness is large, the effect of nitridation is restricted in the surface layer of the protective film, and the protective film as a whole maintains its functions such as corrosion resistance. However, when the protective film thickness is small, the nitridation affects over the entire protective film and, therefore, can decrease corrosion resistance.

Therefore, it is an object of the present invention to provide a method for manufacturing a protective film of a smaller thickness that makes it possible to prevent the protective film from degradation and maintain corrosion resistance at the same time. More specifically, it is an object of the present invention to provide a method for manufacturing a protective film of a smaller thickness that makes it possible to impart desirable properties by surface nitridation and also prevent the protective film from degradation and maintain corrosion resistance.

### SUMMARY OF THE INVENTION

A method for manufacturing a carbon-containing protective film according to the first embodiment of the present invention includes: (a) a step of forming a carbon material film on a substrate by a plasma CVD method using a starting material gas containing a hydrocarbon gas; and (b) a step of nitriding the carbon material film by using plasma generated from a nitrogen-containing starting material gas in a plasma CVD device having an anode and a cathode, and forming a carbon-containing protective film, wherein in step (b), an anode potential is equal to or greater than 20 V, an ion acceleration potential difference is within a range of 20 V to 120 V, and a substrate current density is within a range of 4×10⁻⁶ A/mm² to 8×10⁻⁶ A/mm². The thickness of the carbon material film which is formed is preferably equal to or less than 2.5 nm. A nitridation amount in step (b) is preferably within a range of 6 at % to 20 at %.

A method for manufacturing a magnetic recording medium according to the second embodiment of the present embodiment uses the method for manufacturing a carbon-containing protective film according to the first embodiment. More specifically, the method for manufacturing a magnetic recording medium according to the second embodiment of the present invention includes: (1) a step of forming a magnetic recording medium constituting layer on a nonmagnetic substrate, the magnetic recording medium constituting layer including at least a magnetic recording layer; (2) a step of forming a carbon-containing protective film on the magnetic recording medium constituting layer by the manufacturing method according to the first embodiment; and (3) a step of forming a lubricating layer on the carbon-containing protective film.

By using the aforementioned features, it is possible to perform the nitridation of a carbon material film having a small thickness equal to or less than 2.5 nm, without adversely affecting the corrosion resistance. The obtained carbon-containing protective film is particularly suitable as a protective film for a magnetic recording medium. This is because the obtained carbon-containing protective film has good coupling ability with respect to a lubricating layer that is formed thereupon and, at the same time, has a small thickness that makes it possible to prevent loss attributed to magnetic spacing.

### BRIEF DESCRIPTION OF THE DRAWING

FIG. 1 is a schematic cross-sectional view illustrating a configuration example of a magnetic recording medium manufactured in the second embodiment of the present invention.

### DETAILED DESCRIPTION OF THE INVENTION

The method for manufacturing a carbon-containing protective film according to the first embodiment of the present invention includes: (a) a step of forming a carbon material film on a substrate by a plasma CVD method using a starting material gas including a hydrocarbon gas; and (b) a step of nitriding the carbon material film by using plasma generated from a nitrogen-containing starting material gas in a plasma generating device having an anode and a cathode, and forming a carbon-containing protective film.

The substrate used in step (a) is selected from a magnetic recording medium semi-product, a part of a magnetic tape drive mechanism, a jig, and a mold. The “magnetic recording medium semi-product”, as referred to herein, has a structure including at least a nonmagnetic substrate and a magnetic recording layer formed on the nonmagnetic substrate, the uppermost layer being the magnetic recording layer.

The carbon material film is formed using a plasma chemical vapor deposition (CVD) method with a hydrocarbon gas as a starting material gas. With the plasma CVD method, plasma is generated from the starting material gas, and active radicals or active ions contained in the plasma are deposited on the substrate surface, thereby forming a material film on the substrate surface. The carbon material film that is preferably formed in the invention of the present application is an amorphous carbon film. From the standpoint of surface smoothness and hardness, a DLC film is preferred among amorphous carbon films.

The power for generating plasma from the starting material gas may be supplied by a capacitively coupled system or inductively coupled system. The supplied power can be DC power, HF power (frequency from several tens of kilohertz to several hundreds of kilohertz), RF power (frequency: 13.56 MHz, 27.12 MHz, 40.68 MHz etc.), and microwaves (frequency 2.45 GHz etc.).

The starting material gases that can be used in step (a) include hydrocarbons such as methane (CH₄), ethane (C₂H₆), ethylene (C₂H₄), acetylene (C₂H₂), and propane (C₃H₈). A mixture of two or more hydrocarbon gases may be also used. A mixture of one or a plurality of hydrocarbon gases and one or a plurality of fluorocarbon gases and/or hydrofluorocarbon gases may be also used. Tetrafluoromethane (CF₄) is a fluorocarbon that can be used. The starting material gas may also include an inactive gas such as helium and argon.

Examples of plasma CVD device that can be used in step (a) include a plasma CVD device of a parallel plate type, a filament-type plasma CVD device, an ECR-type plasma CVD device, and a helicon wave plasma CVD device. In the present invention, it is preferred that a filament-type plasma CVD device be used in which thermoelectrons generated by supplying an electric current of a filament cathode are accelerated toward an anode, and plasma is generated by collisions of the accelerated thermoelectrons with starting material gas molecules.

The carbon material film formed in step (a) has a thickness of 1.2 nm to 2.5 nm, preferably 1.2 nm to 2.0 nm. Where the film thickness is equal to or greater than 1.2 nm, the protective film formed in step (b) can be imparted with good corrosion resistance. As a result of forming the film with a thickness equal to or less than 2.5 nm, it is possible to obtain a magnetic recording medium having a small magnetic spacing and good electromagnetic conversion property when the finally obtained carbon protective film is used as a protective film for a magnetic recording medium.

In step (b), the carbon material film formed in step (a) is nitrided and a carbon-containing protective film is formed. The carbon-containing protective film obtained by nitridation in step (b) has excellent surface smoothness. In particular, when this film is used as a protective film for a magnetic recording medium, by nitridation treatment an excellent FOD characteristic can be obtained since sufficient coupling can be ensured between the carbon-containing protective film and the lubricating layer formed thereupon.

The plasma generating devices having an anode and a cathode, which can be used in step (b) include a filament-type plasma CVD device in which the bias potential with respect to the substrate can be set independently.

Examples of the nitrogen-containing starting material gas that can be used in step (b) include nitrogen (N₂) and nitrous oxide (N₂O). The nitrogen-containing starting material gas may further include an inactive gas such as helium and argon.

The anode potential E_{A} is positive with respect to the filament cathode in order to ensure sufficient acceleration of the electrons emitted from the filament cathode. In the present invention, it is preferred that the anode potential E_{A} be equal to or higher than +20 V. As a result of using an anode potential E_{A} equal to or higher than +20 V, it is possible to realize a stable plasma discharge. In the present invention, the “electric potential” is defined as a potential with respect to a ground state.

The bias potential E_{V} applied to a layered body of the substrate and the carbon material film is lower than the anode potential E_{A} to accelerate nitrogen-containing ions. In the present invention, it is preferred that the ion acceleration potential difference defined as E_{A}−E_{V} be within a range of 20 V to 120 V. As a result of the ion acceleration potential difference being equal to or higher than 20 V, it is possible to realize a stable plasma discharge. Further, by making the ion acceleration potential difference equal to or less than 120 V, it is possible to prevent the carbon-containing protective film from degradation. More specifically, by preventing the ion acceleration potential difference from being excessively high, it is possible to inhibit the detachment of hydrogen atoms (H) from C—H bonds present in DLC and prevent the DLC with a tetrahedral structure from changing into the carbon-containing protective film with a graphite structure.

Further, in step (b), it is preferred that the substrate current density iₛ be within a range of 4×10⁻⁶ A/mm² to 8×10⁻⁶ A/mm². In the present invention, the substrate current density iₛ means a value obtained by dividing the electric current, which flows because nitrogen-containing ions contained in the plasma reach the carbon material layer, by the surface area of the substrate where a film is to be formed. As a result of the substrate current density iₛ being equal to or higher than 4×10⁻⁶ A/mm², it is possible to realize a stable plasma discharge. As a result of the substrate current density iₛ being equal to or lower than 8×10⁻⁶ A/mm², it is possible to prevent the carbon-containing protective film from degradation. More specifically, by preventing the substrate current density iₛ from being excessively high, it is possible to inhibit the detachment of hydrogen atoms (H) from C—H bonds present in DLC and prevent the coupling state of carbon constituting the DLC from changing from a tetrahedral structure into the a graphite structure.

In step (b), the nitridation amount of the carbon-containing protective film that is formed can be controlled by controlling the ion acceleration potential difference, substrate current density iₛ, and nitridation time. In the present invention, the “nitridation amount” of the carbon-containing protective film means a ratio (N/(C+N+O)), i.e. a ratio of the number of nitrogen atoms to the sum total of the number of carbon and nitrogen atoms in the carbon-containing protective film and the number of oxygen atoms adsorbed on the surface of the carbon-containing protective film. The “nitridation amount” of the carbon-containing protective film can be measured by an analytical method such as an X-ray photoelectron spectroscopy (XPS).

It is preferred that the nitridation amount in step (b) be 6 at % to 20 at %. As a result of the nitridation amount being equal to or less than 20 at %, it is possible to prevent the protective film from degradation. More specifically, by avoiding excessive nitridation, it is possible to prevent the tetrahedral structure from changing into the graphite structure. Further, when the film obtained is used as a protective film for a magnetic recording medium, as a result of the nitridation amount being equal to or greater 6 at %, it is possible to ensure sufficient coupling between the carbon-containing protective film and the lubricating layer formed thereupon.

By controlling the ion acceleration potential difference, substrate current density iₛ, and nitridation amount in the above-described manner, it is possible to prevent the carbon material film from being degraded by the nitridation treatment and provide a carbon-containing protective film having a small thickness equal to or less than 2.5 nm and excellent corrosion resistance. Further, the carbon-containing protective film obtained by the nitridation treatment of step (b) has the same thickness as the carbon material film prior to the treatment. Accordingly, the carbon-containing protective film obtained in step (b) has a thickness of 1.2 nm to 2.5 nm, preferably 1.2 nm to 2.0 nm. Where the carbon-containing protective film obtained in the above-described steps (a) and (b) is used as a protective film for magnetic recording medium, it is possible to obtain a magnetic recording medium with a small magnetic spacing and good electromagnetic conversion characteristic.

A method for manufacturing a magnetic recording medium according to the second embodiment of the present invention uses the method for manufacturing a carbon-containing protective film according to the first embodiment. More specifically, the method for manufacturing a magnetic recording medium according to the second embodiment of the present invention includes: (1) a step of forming a magnetic recording medium constituting layer on a nonmagnetic substrate, the magnetic recording medium constituting layer including at least a magnetic recording layer; (2) a step of forming a carbon-containing protective film by the manufacturing method according to the first embodiment; and (3) a step of forming a lubricating layer on the carbon-containing protective film.

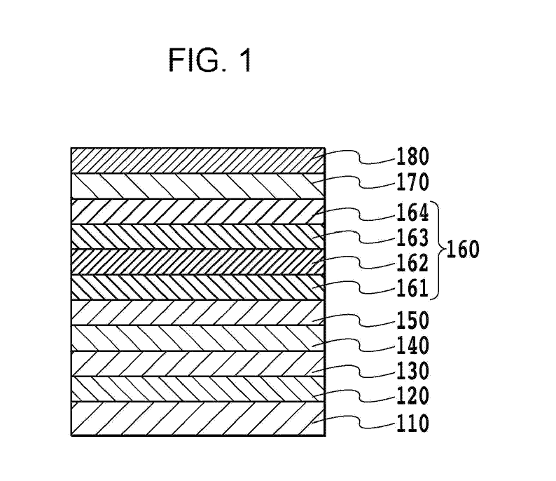

FIG. 1 shows a configuration example of the magnetic recording medium manufactured in the second embodiment of the present invention. The magnetic recording medium shown in FIG. 1 includes a nonmagnetic substrate 110, a nonmagnetic underlayer 120, a soft magnetic layer 130, a seed layer 140, an interlayer 150, a magnetic recording layer 160, a carbon-containing protective film 170, and a lubricating layer 180. Among those layers, the nonmagnetic substrate 110, magnetic recording layer 160, carbon-containing protective film 170, and lubricating layer 180 are necessary constituent layers, and other layers may be provided selectively.

Step (1) of the present embodiment is a step of forming the constituent layers of the magnetic recording medium including at least the magnetic recording layer on the nonmagnetic substrate 110.

The nonmagnetic substrate 110 can be fabricated from any material that has been conventionally used for manufacturing a magnetic recording medium. For example, the nonmagnetic substrate 110 can be fabricated by using an aluminum alloy plated with Ni-P, glass, ceramics, plastics, and silicon.

The magnetic recording layer 160 may have a single layer structure or a layered structure constituted by a plurality of layers. The magnetic recording layer 160 includes at least one magnetic layer. In the magnetic recording medium shown in FIG. 1, the magnetic recording layer 160 includes a first magnetic layer 161, a coupling control layer 162, a second magnetic layer 163, and a third magnetic layer 164.

The magnetic layers in the magnetic recording layer 160 can be formed using, for example, a ferromagnetic material such as an alloy including Co and Pt. It is also preferred that the axis of easy magnetization of the ferromagnetic material be aligned along the direction in which magnetic recording is to be performed. For example, when perpendicular magnetic recording is to be performed, the axis of easy magnetization of the ferromagnetic material of the magnetic layer should be oriented in the direction perpendicular to the recording medium surface (that is, the principal flat surface of the substrate). When the ferromagnetic material has a hexagonal closely packed (hcp) structure, the axis of each magnetization is a c-axis. Alternatively, the magnetic layer is formed using a ferromagnetic material having a granular structure in which magnetic crystal grains are disposed in a matrix of a nonmagnetic oxide or a nonmagnetic nitride. Examples of the ferromagnetic materials having a granular structure that can be used include CoPt—SiO₂, CoCrPtO, CoCrPt—SiO₂, CoCrPt—TiO₂, CoCrPt—Al₂O₃, CoPt—AlN, and CoCrPt—Si₃N₄, but the materials are not limited to those examples. In the magnetic recording medium shown in FIG. 1, the first magnetic layer 161 and the second magnetic layer 163 are preferably formed using a ferromagnetic material having a granular structure. In the present invention the use of a ferromagnetic material having a granular structure is preferred from the standpoint of enhancing magnetic separation between the adjacent magnetic crystal grains in the magnetic recording layer and improving medium properties such as noise reduction, increase in SNR, and improvement of magnetic resolution.

In the magnetic recording layer 160 having a layered structure constituted by a plurality of layers, the magnetic layers may be formed from the same ferromagnetic material or from different ferromagnetic materials. By using a layered structure constituted by a plurality of magnetic layers, it is possible to perform flexible control of the magnetic characteristic of the magnetic recording layer 160 according to the characteristic of the magnetic head used for read/write and to inhibit noise occurring in the magnetic recording layer 160.

As shown in the magnetic recording medium in FIG. 1, the coupling control layer 162 may be formed between the first magnetic layer 161 and the second magnetic layer 163 formed from a material having a granular structure. The coupling control layer 162 can be formed, for example, from V, Cr, Fe, Co, Ni, Cu, Nb, Mo, Ru, Rh, Ta, W, Re, Ir, or alloys having those metals as the main component. The coupling control layer has a function of controlling the exchange coupling between the first magnetic layer 161 and the second magnetic layer 163. By controlling the exchange coupling between those magnetic layers to an appropriate value, it is possible to adjust the magnetization reversal field of the entire magnetic recording layer 160.

Further, as shown in the magnetic recording medium in FIG. 1, a third magnetic layer 164 of a non-granular structure may be formed on the second magnetic layer 163. The third magnetic layer of a non-granular structure is effective in blocking Co atoms eluting through the nonmagnetic matrix of the granular structure and maintaining high durability of the magnetic recording medium. The material having a non-granular structure preferably includes metal crystal grains constituted, for example, by an alloy including Co and Pt and nonmagnetic crystal grain boundaries from a metal and does not include metal oxides or nitrides. The metal constituting a nonmagnetic crystal grain boundary includes at least one element selected from the group consisting of Ta, Pt, B, Si, Nb, and Cu. Among them, it is preferred that B be used as a material of the nonmagnetic grain boundary because it demonstrates excellent performance in magnetically separating magnetic crystal grains constituted by a Co-based alloy.

The nonmagnetic underlayer 120 that may be selectively provided can be formed using a nonmagnetic material including Cr, such as a CrTi alloy, or a nonmagnetic material including Ti.

The soft magnetic layer 130 that may be selectively provided can be formed using a crystalline material such as FeTaC and Sendust (FeSiAl), a microcrystalline material such as FeTaC, CoFeNi, and CoNiP, and an amorphous material including a Co alloy such as CoZrNd, CoZrNb, and CoTaZr. The soft magnetic layer 130 has a function of concentrating the perpendicular magnetic field generated by the magnetic field in a perpendicular magnetic recording medium in the magnetic recording layer 160. The optimum value of the thickness of the soft magnetic layer 130 varies depending on the structure and properties of the magnetic head used for recording. Where productivity is taken into account, it is generally preferred that the soft magnetic layer 130 have a thickness within a range of 10 nm to 150 nm.

The seed layer 140 that may be selectively provided can be formed using a Permalloy material such as NiFeAl, NiFeSi, NiFeNb, NiFeB, NiFeNbB, NiFeMo, and NiFeCr; a material obtained by further adding Co to a Permalloy material, such as CoNiFe, CoNiFeSi, CoNiFeB, and CoNiFeNb; Co; or a Co-based alloy such as CoB, CoSi, CoNi, and CoFe. The seed layer 140 preferably has a thickness sufficient for controlling the crystal structure of the magnetic recording layer 160. It is usually preferred that the seed layer 140 have a thickness within a range of 3 nm to 50 nm.

The interlayer 150 that may be selectively provided can be formed using Ru or an alloy containing Ru as the main component. The interlayer 150 preferably has a thickness within a range of 0.1 nm to 20 nm. As a result of the interlayer 150 having the thickness within this range, it is possible to impart the magnetic recording layer 160 with properties necessary for high-density recording, without causing degradation of magnetic properties and electromagnetic conversion characteristic of the magnetic recording layer 160.

The constituent layers from the nonmagnetic underlayer 120 to the magnetic recording layer 160 can be formed using any method known in the art, for example, a sputtering method (including a DC magnetron sputtering method and an RF magnetron sputtering method) and a vacuum vapor deposition method.

Step (2) of the present embodiment includes a sub-step of forming a carbon material film by a plasma CVD method using a starting material gas including a hydrocarbon gas on the magnetic recording medium constituent layers and a sub-step of nitriding the carbon material film and forming a carbon-containing protective film 170 by a plasma CVD method using nitrogen gas as a starting material gas in a plasma CVD device having an anode and a cathode. This step can be implemented in the same manner as step (b) of the first embodiment.

In step (3) of the present embodiment, the lubricating layer 180 is formed on the carbon-containing protective film 170.

The lubricating layer 180 serves to impart lubricating ability when a magnetic head comes into contact with the magnetic recording medium. The lubricating layer 180 can be formed on the substrate by using a liquid lubricant material well known in the pertinent technical field. More specifically, it is preferred that a perfluoropolyether (PFPE) liquid lubricant be used. The lubricating layer can be formed by coating a liquid lubricant on the carbon-containing protective film 170 by a dip coating method or a spin coating method. More specific examples of the liquid lubricant include Fomblin® Z-tetraol (manufactured by Solvay Solexis) and Moresco Phosphanol A2OH (manufactured by MORESCO).

The lubricating layer 180 preferably has a thickness within a range of 0.7 nm to 1.8 nm. As a result of the thickness being equal to or greater than 0.7 nm, it is possible to impart the lubricating layer with good durability. Meanwhile, as a result of the thickness being equal to or less than 1.8 nm, it is possible to reduce a loss caused by magnetic spacing and provide a magnetic recording medium having a good magnetic conversion characteristic.

### EXAMPLES

### Example 1

### (1) Formation of Constituent Layers of Magnetic Recording Medium

A nonmagnetic substrate was prepared by plating a Ni—P film with a thickness of 12 tm on the surface of an annular aluminum disk with an outer diameter of 95 mm, an inner diameter of 25 mm, and a thickness of 1.27 mm. The obtained nonmagnetic substrate was smoothened and cleaned.

Then the following constituent layers of a magnetic recording medium were formed in the order of description on the cleaned nonmagnetic substrate by using a DC magnetron sputtering method. A nonmagnetic underlayer constituted by Cr₅₀Ti₅₀ and having a thickness of 6.0 nm. A soft magnetic layer constituted by CoZrNb and having a thickness of 20 nm. A seed layer constituted by CoNiFe and having a thickness of 8.0 nm. An interlayer constituted by Ru and having a thickness of 10 nm. A first magnetic layer of a granular structure constituted by CoCrPt—SiO₂ and having a thickness of 10 nm. A coupling control layer constituted by Ru and having a thickness of 0.2 nm. A second magnetic layer of a granular structure constituted by CoCrPt—SiO₂ and having a thickness of 3.0 nm. A third magnetic layer having a non-granular structure constituted by CoCrPt—B and having a thickness of 6.0 nm.

In this case, the magnetic recording layer is constituted by four layers, namely, the first magnetic layer, coupling control layer, second magnetic layer, and third magnetic layer, as shown in FIG. 1.

### Example 1

### (2) Formation of Carbon Material Film

Then, a carbon material film was formed on the obtained magnetic recording layer by using a plasma CVD method. Plasma was generated by using a filament-type plasma CVD device and introducing ethylene (C₂H₄) gas as a starting material gas into the device, while supplying a predetermined electric current to the cathode filament to cause the emission of thermoelectrons. The following reaction conditions were used: the ethylene (C₂H₄) gas flow rate was 50 sccm, the anode potential E_{A} was +60 V, the bias potential E_{V} was −120 V, and the substrate temperature was about 180° C. A carbon material film constituted by DLC and having a thickness of 2.0 nm was formed by adjusting the film deposition time.

The term “sccm” hereinabove means a flow rate (units: cm³) per 1 min under standard conditions (1 atm (0.1013 MPa)/0° C.).

### Example 1

### (3) Formation of Carbon-Containing Protective Film

The obtained carbon material film was then subjected to nitridation treatment. Plasma was generated by using a filament-type plasma CVD device and introducing nitrogen gas as a nitrogen-containing starting material gas into the device, while supplying a predetermined electric current to the cathode filament to cause the emission of thermoelectrons. The following reaction conditions were used: nitrogen gas flow rate was 40 sccm, the anode potential E_{A} was +40 V, the bias potential E_{V} was −40 V, the substrate current density was 6×10⁻⁶ A/mm² and the substrate temperature was about 180° C. Thus, the ion acceleration potential difference was 80 V. A carbon-containing protective film with a nitrogen amount of 13 at % was obtained by adjusting the treatment time.

### Example 1

### (4) Formation of Lubricating Layer

Finally, a magnetic recording medium was obtained by forming a lubricating layer on the obtained carbon-containing protective film. By implementing dip coating, the lubricating layer with a thickness of 1.0 nm was formed by coating a liquid lubricant containing Fomblin® Z-tetraol (HOCH₂CH(OH)CH₂—OCH₂CF₂O—(CF₂CF₂O)ₙ—(CF₂O)ₘ—CF₂CH₂O—CH₂CH(OH)CH₂OH, molecular weight=2000 to 4000) as the main component.

### Example 1

### (5) Evaluation of Corrosion Resestance

A total of 0.5 mL of an aqueous solution of nitric acid of a predetermined concentration (3.0%) was dropped on each of four points arranged with a 90° spacing on the obtained annular magnetic recording medium, the magnetic recording medium was allowed to stay for 60 min, and Co contained in the magnetic recording layer was caused to elute. The contact surface area of the aqueous solution of nitric acid was measured. Then, the solution located on the magnetic recording medium was recovered and the eluted Co was analyzed by an inductively coupled plasma mass spectrometry (ICP-MS). The concentration of Co in the solution was determined using a calibration curve obtained with a standard sample. The obtained Co concentration was recalculated in the amount (units: nanogram (ng)) of Co per unit contact surface area (units: cm²) of the aqueous solution of nitric acid by using the volume and contact surface area of the aforementioned aqueous solution of nitric acid and was evaluated as “Co elution amount”. The Co elution amount in the present embodiment was good (0.021 ng/cm²).

In the present invention, a Co elution amount of 0.040 ng/cm² was taken as a reference value for determining whether the corrosion resistance is “Good”. In the magnetic recording medium with the Co elution amount equal to or lower than this numerical value, no adverse effect is produced on reliability evaluation of a recording device such as a hard disk drive.

### Examples 2 to 4

Magnetic recording media were obtained by the same procedure as in Example 1, except that the ion acceleration potential difference was fixed to 80 V and the anode potential E_{A} and the bias potential E_{V} were varied in step (3). The corrosion resistance of the obtained magnetic recording media was evaluated by the same procedure as in Example 1. The results are shown in Table 1.

### Example 5

A magnetic recording medium was obtained by the same procedure as in Example 1, except that the anode potential E_{A} of +20 V and the bias potential E_{V} of ±0 V were used and the ion acceleration potential difference was changed to 20 V in step (3). The corrosion resistance of the obtained magnetic recording media was evaluated by the same procedure as in Example 1. The results are shown in Table

### Examples 6 and 7

Magnetic recording media were obtained by the same procedure as in Example 1, except that the anode potential E_{A} and the bias potential E_{V} were varied and the ion acceleration potential difference was changed to 40 V in step (3). The corrosion resistance of the obtained magnetic recording media was evaluated by the same procedure as in Example 1. The results are shown in Table 1.

### Examples 8 to 10

Magnetic recording media were obtained by the same procedure as in Example 1, except that the anode potential E_{A} and the bias potential E_{V} were varied and the ion acceleration potential difference was changed to 60 V in step (3). The corrosion resistance of the obtained magnetic recording media was evaluated by the same procedure as in Example 1. The results are shown in Table 1.

### Examples 11 to 15

Magnetic recording media were obtained by the same procedure as in Example 1, except that the anode potential E_{A} and the bias potential E_{V} were varied and the ion acceleration potential difference was changed to 100 V in step (3). The corrosion resistance of the obtained magnetic recording media was evaluated by the same procedure as in Example 1. The results are shown in Table 1.

### Examples 16 to 21

Magnetic recording media were obtained by the same procedure as in Example 1, except that the anode potential E_{A} and the bias potential E_{V} were varied and the ion acceleration potential difference was changed to 120 V in step (3). The corrosion resistance of the obtained magnetic recording media was evaluated by the same procedure as in Example 1. The results are shown in Table 1.

### Examples 22 to 28

Magnetic recording media were obtained by the same procedure as in Example 1, except that the anode potential E_{A} and the bias potential E_{V} were varied and the ion acceleration potential difference was changed to 140 V in step (3). Those examples are comparative examples which are outside the scope of the present invention. The corrosion resistance of the obtained magnetic recording media was evaluated by the same procedure as in Example 1. The results are shown in Table 1.

TABLE 1
Ion acceleration potential difference in nitridation
treatment and evaluation of corrosion resistance of
the obtained magnetic recording medium^{†.}

| | Ion acceleration | Anode | Bias | Evaluation of |
|---|---|---|---|---|
| Exam- | potential | potential | potential | corrosion resistance |
| ple | difference (V) | E_{A} (V) | E_{V} (V) | (ng/cm²) |
| 5 | 20 | 20 | 0 | 0.015 |
| 6 | 40 | 40 | 0 | 0.017 |
| 7 | | 20 | −20 | 0.016 |
| 8 | 60 | 60 | 0 | 0.018 |
| 9 | | 40 | −20 | 0.019 |
| 10 | | 20 | −40 | 0.018 |
| 2 | 80 | 80 | 0 | 0.020 |
| 3 | | 60 | −20 | 0.022 |
| 1 | | 40 | −40 | 0.021 |
| 4 | | 20 | −60 | 0.020 |
| 11 | 100 | 100 | 0 | 0.025 |
| 12 | | 80 | −20 | 0.025 |
| 13 | | 60 | 40 | 0.025 |
| 14 | | 40 | −60 | 0.026 |
| 15 | | 20 | −80 | 0.024 |
| 16 | 120 | 120 | 0 | 0.034 |
| 17 | | 100 | −20 | 0.033 |
| 18 | | 80 | −40 | 0.035 |
| 19 | | 60 | −60 | 0.034 |
| 20 | | 40 | −80 | 0.035 |
| 21 | | 20 | −100 | 0.032 |
| 22 | 140 | 140 | 0 | 0.057 |
| 23 | | 120 | −20 | 0.058 |
| 24 | | 100 | −40 | 0.059 |
| 25 | | 80 | −60 | 0.056 |
| 26 | | 60 | −80 | 0.058 |
| 27 | | 40 | −100 | 0.056 |
| 28 | | 20 | −120 | 0.057 |

^{†}Substrate current density iₛ = 6 × 10⁻⁶ A/mm², substrate temperature is about 180° C., and nitridation amount = 13 at %.

As follows from Table 1, where the ion acceleration potential difference was within a range of 20 V to 120 V, good corrosion resistance evaluation result with a Co elution amount equal to or less than 0.040 ng/cm² was obtained (Examples 1 to 21). Meanwhile, in Examples 22 to 28 in which the ion acceleration potential difference was 140 V, the Co elution amount increased and corrosion resistance of the magnetic recording medium degraded.

In each set of Examples 1 to 4 (80 V), Examples 6 and 7 (40 V), Examples 8 to 10 (60 V), Examples 11 to 15 (100 V), Examples 16 to 21 (120 V), and Examples 22 to 28 (140 V), in which the ion acceleration potential difference was the same, variations in the anode potential E_{A} and the bias potential E_{V} were not found to cause significant variations in corrosion evaluation. This result demonstrated that ion acceleration potential difference is the main factor affecting the corrosion resistance of magnetic recording media.

In Examples 1 to 28, stable plasma discharge was observed. This stable plasma discharge was apparently demonstrated because the anode potential E_{A} was set to a value equal to or higher than +20 V.

### Examples 29 to 31

Magnetic recording media were obtained by repeating the procedure of Example 1, except that the substrate current density was varied by varying the amount of emitted thermoelectrons by adjusting the temperature of the filament cathode in step (3). Example 31 is a comparative example which is outside the scope of the present invention. In Examples 29 to 31, the nitridation treatment time was adjusted and a carbon-containing protective film with a nitridation amount of 13 at % was formed. The corrosion resistance of the obtained magnetic recoding media was evaluated by the same procedure as in Example 1. The results are shown in Table 2.

TABLE 2
Substrate current density in nitridation treatment, and evaluation
of corrosion resistance of the obtained magnetic recording medium^{†}

| | Substrate current | Evaluation of corrosion |
|---|---|---|
| Example | density iₛ (×10⁻⁶ A/mm²) | resistance (ng/cm²) |
| 29 | 4 | 0.015 |
| 1 | 6 | 0.021 |
| 30 | 8 | 0.037 |
| 31 | 10 | 0.063 |

^{†}Anode potential E_{A} = +40 V, Bias potential E_{V} = −40 V, Substrate temperature is about 180° C., and Nitridation amount = 13 at %.

As clearly shown in Table 2, in Examples 1, 29, and 30 in which the substrate current density iₛ was within a range of 4×10⁻⁶ A/mm² to 8×10⁻⁶ A/mm, good evaluation of corrosion resistance with a Co elution amount equal to or less than 0.040 ng/cm² was obtained. Meanwhile, in Example 31 in which the substrate current density iₛ was 10×10⁻⁶ A/mm², the Co elusion amount increased and the corrosion resistance of the magnetic recording medium decreased.

### Examples 32 to 36

Magnetic recording media were obtained by repeating the procedure of Example 1, except that the nitridation amount was varied by adjusting the nitridation treatment time in step (3). Example 36 is a comparative example which is outside the scope of the present invention. The corrosion resistance of the obtained magnetic recording media was evaluated by the same procedure as in Example 1. The results are shown in Table 3.

TABLE 3
Nitridation amount in nitridation treatment, and corrosion
evaluation of obtained magnetic recording media^{†}

| | Nitridation | Evaluation of corrosion |
|---|---|---|
| Examples | amount (at %) | resistance (ng/cm²) |
| 32 | 6 | 0.015 |
| 33 | 9 | 0.017 |
| 1 | 13 | 0.021 |
| 34 | 17 | 0.029 |
| 35 | 20 | 0.037 |
| 36 | 23 | 0.047 |

^{†}Anode potential E_{A} = +40 V, Bias potential E_{V} = −40 V, Substrate current potential iₛ = 6 × 10⁻⁶ A/mm², and Substrate temperature is about 180° C.

As clearly follows from Table 2, in Examples 1 and 32 to 35 in which the nitridation amount was within a range of 6 at % to 20 at %, good corrosion resistance evaluation with a Co elution amount equal to or less than 0.040 ng/cm² was obtained. Meanwhile, in Example 36 in which the nitridation amount was 23 at %, the Co elution amount increased and the corrosion resistance of the magnetic recording medium decreased.

### EXPLANATION OF REFERENCE NUMERALS

110 nonmagnetic substrate

120 nonmagnetic underlayer

130 soft magnetic layer

140 seed layer

150 interlayer

160 magnetic recording layer

161 first magnetic recording layer

162 coupling control layer

163 second magnetic recording layer

164 third magnetic recording layer

170 carbon-containing protective film

180 lubricating layer

What is claimed is:

1. A method for manufacturing a carbon-containing protective film, the method comprising:
(a) forming a carbon material film on a substrate by a plasma CVD method using a starting material gas containing a hydrocarbon gas; and
(b) nitriding the carbon material film by using plasma generated from a nitrogen-containing starting material gas in a plasma CVD device having an anode and a cathode, to form the carbon-containing protective film under conditions including an anode potential equal to or greater than 20 V, an ion acceleration potential difference within a range of 20 V to 120 V, and a substrate current density within a range of 4×10⁻⁶ A/mm² to 8×10⁻⁶ A/mm².

2. The method for manufacturing a carbon-containing protective film according to claim 1, wherein the carbon material film has a thickness that is equal to or less than 2.5 nm.

3. The method for manufacturing a carbon-containing protective film according to claim 1, wherein nitriding the carbon material film provides a nitridation amount within a range of 6 at % to 20 at %.

4. A method for manufacturing a magnetic recording medium, the method comprising:
(a) forming a magnetic recording medium constituting layer on a nonmagnetic substrate, the magnetic recording medium constituting layer including at least a magnetic recording layer;
(b) forming a carbon-containing protective film on the magnetic recording medium constituting layer by the manufacturing method according to claim 1; and
(c) forming a lubricating layer on the carbon-containing protective film.

5. The method for manufacturing a magnetic recording medium according to claim 4, wherein the carbon material film has a thickness that is equal to or less than 2.5 nm.

6. The method for manufacturing a magnetic recording medium according to claim 4, wherein nitriding the carbon material film provides a nitridation amount within a range of 6 at % to 20 at %.

7. A method for manufacturing a carbon-containing protective film, the method comprising:
(a) forming a carbon material film on a substrate by a plasma CVD method using a starting material gas containing a hydrocarbon gas; and
(b) nitriding the carbon material film by using plasma generated from a nitrogen-containing starting material gas in a plasma CVD device having an anode and a cathode, to form the carbon-containing protective film under conditions including an ion acceleration potential difference within a range of 20 V to 120 V.

8. A method for manufacturing a magnetic recording medium, the method comprising:
(a) forming a magnetic recording medium constituting layer on a nonmagnetic substrate, the magnetic recording medium constituting layer including at least a magnetic recording layer;
(b) forming a carbon-containing protective film on the magnetic recording medium constituting layer by the manufacturing method according to claim 7; and
(c) forming a lubricating layer on the carbon-containing protective film.
